(19) United States
(12) Patent Application Publication
(10) Pub. No.: US 2007/0192048 A1
(43) Pub. Date: Aug. 16, 2007

(54) System and method for estimating phase offset in a communication system

(75) Inventors: Saigui Hu, Singapore (SG); Changqing Xu, Singapore (SG); Zhiping Ll, Singapore (SG); Tingwu Wang, Singapore (SG); Kai Ren Tan, Singapore (SG); Masayuki Tomisawa, Singapore (SG)

Correspondence Address: VENABLE LLP, P.O. BOX 34385, WASHINGTON, DC, 20043-9998, US

(73) Assignee: Oki Techno Centre (Singapore) Pte Ltd, Singapore (SG)

(21) Appl. No.: 11/638,708

(22) Filed: Dec. 14, 2006

(30) Foreign Application Priority Data
Dec. 14, 2005 (SG) 200508066-8

(51) Int. Cl. G01R 29/26; G06F 19/00

(52) U.S. Cl. 702/69; 702/189; 702/85; 702/89; 702/66; 702/1

(57) ABSTRACT

A system and method for estimating phase offset between a local oscillator and a transmitted input signal in a communication system comprises a differential detector and a phase compensation stage for compensating for phase errors in an output signal from the differential detector. The output signal from the differential detector is rotated in a decision-based rotation stage coupled to the outputs of the differential detector and the phase compensation stage. The rotation is based on a decision made using the output signal from the phase compensation stage. An accumulation stage accumulates the output signal from the decision-based rotation stage for a number of symbols in the transmitted input signal. A normalization stage normalizes the output signal from the accumulation stage and the normalized output signal corresponds to a phase offset of the local oscillator relative to the transmitted input signal. The phase compensation stage has a further input to which the phase offset is applied to compensate the phase of a subsequently received symbol in the transmitted input signal. The phase offset between the local oscillator and the transmitted input signal is then estimated.

### FIELD OF THE INVENTION

The present invention relates to a system and method for estimating phase offset in a communication system, and in particular to a system and method for estimating phase offset in a system for demodulating a signal modulated according to a differential phase shift keying (DPSK) modulation scheme such as signals modulated according to a Differential Quadrature Phase Shift Keying (DQPSK) modulation scheme. The present invention also relates to a receiver comprising such a system, a method for processing received signals comprising such a method and a demodulation apparatus and method for decoding data. Also, the present invention relates to a combined signal detection and phase estimation system and method.

### BACKGROUND OF THE INVENTION

Differential phase shift keying (DPSK) modulation schemes are widely used in wireless communications systems. In DPSK modulation schemes, such as Differential Quadrature Phase Shift Keying (DQPSK) and Differential Bi-Phase Shift Keying (DBPSK) schemes, the phase of the carrier is discretely varied in relation to the phase of the immediately preceding signal element and in accordance with the data being transmitted.

When receiving and de-modulating a digitally modulated signal, ideally, the transmitter generates a carrier signal at a known frequency and the received signals are then demodulated at the receiver to recover the data being transmitted. A signal obtained from a local oscillator is typically used in the demodulation process, the signal used being nominally at the same frequency as the transmitter carrier.

One problem with digital communication in general is the residual carrier frequency offset due to inaccuracies in the transmitter and receiver oscillators, along with the effect of Doppler Shifting. If the frequency offset is excessive and not suitably compensated, the performance of the demodulator will be degraded and the original signal may not be recoverable.

Residual frequency offset is conventionally compensated for using a phase locked loop technique in which the received carrier phase is continuously tracked for frequency offset compensation. Another conventional approach for compensating for residual frequency offset is to use a forward frequency estimation technique in which the frequency offset is estimated at regular intervals. In such an approach, frequency estimation may be simplified by using DBPSK, DQPSK or

$$\frac{π}{4}$$

DQPSK modulation schemes, as only a small phase difference between two adjacent symbols affects the data demodulation. This phase difference corresponds to the frequency offset.

One conventional procedure for estimating and correcting the frequency offset is described in Proakis, Digital Communications, “Chapter 6: Carrier and symbol synchronization,” McGraw-Hill International Editions, Singapore, 3rd edition, 1995. In this technique, a differential detector performs differential detection of one symbol span and a phase compensation block is arranged to use the previous estimated value of the phase error using a frequency offset estimation algorithm to compensate for the differential detection output.

U.S. Pat. No. 5,574,399 describes a coherent PSK detector which does not require carrier recovery in which the frequency offset estimation is initially set to zero and is corrected from this value.

U.S. Pat. No. 6,038,267 describes a digital demodulator, a maximum-value selector, and a diversity receiver and presents an improved method for obtaining the frequency offset estimation in which the frequency offset is initially set to a fixed value of approximately the correct order.

FIGS. 1 to 3 illustrate prior art systems including one or more of the systems and procedures of the above-mentioned references and these are described in more detail below.

There are a number of problems in the frequency offset estimation systems and procedures described in the above-mentioned references. Firstly, the algorithms used are complex, including, for example, two trigonometric function calculations, one being the calculation of an arc tangent and the other being a sine/cosine calculation. Another problem with such conventional systems and techniques is that the algorithms tend to rely heavily on the preceding estimation and are therefore not suitable for handling the transition from the state where no data is being transmitted to the state where data is being transmitted. Furthermore, when no data is being transmitted, noise will still be present in the channel and this may affect the frequency offset estimation system resulting in a poor and unstable frequency offset estimation.

Also, one or more of the conventional systems described in the above-mentioned references for estimating the frequency offset include, for example two complex multipliers, such as a differential detector and a phase compensation stage. Other conventional arrangements may include three complex multipliers such as a differential detector, a phase compensation stage and a multiplier after an accumulation stage, as well as a normalization stage. Such systems are therefore complex in both hardware and associated processing software.

In view of the foregoing disadvantages of conventional systems and processing methods, a need exists for a general modulation/demodulation scheme which is cost effective to use and produce and which is not complex.

### SUMMARY OF THE INVENTION

In general terms, the present invention relates to a method and system for estimating the phase offset of two successive symbols caused by the frequency offset and the phase offset between a local oscillator and a transmitted input signal in a communication system. An estimated phase offset value is further applied to an input of a phase compensation stage to correct the phase of the detected signals and the resulting estimated output is related to the total phase offset of two successive symbols caused by the frequency offset and the phase offset. This is in contrast to conventional systems and methods in which the estimated output is generally related to the residual phase offset which requires more complex processing circuitry and algorithms. Thus, in one or more preferred embodiments of the present invention simplification of the hardware implementation may be achieved without performance penalty.

According to a first aspect of the invention there is provided a system for estimating phase offset between a local oscillator and a transmitted input signal in a communication system, the transmitted signal comprising a number of symbols each having an associated phase, the system comprising:
a differential detector stage for receiving a transmitted input signal, the differential detector stage having an input and an output;
a phase compensation stage for compensating for phase errors in an output signal from the differential detector stage, the phase compensation stage having an output;
a decision-based rotation stage couplable to the outputs of the differential detector stage and the phase compensation stage, the decision-based rotation stage having an output signal having a phase, the decision-based rotation stage being arranged to rotate the output signal from the differential detector stage so that the phase of the signal output from the decision-based rotation stage is within a predetermined amount of a predetermined phase angle, the decision-based rotation stage being arranged to rotate the output signal from the differential detector stage based on a decision made using the output signal from the phase compensation stage;
an accumulation stage couplable to receive and accumulate the output signal from the decision-based rotation stage for a number of symbols in the transmitted input signal, the accumulation stage having an output; and
a normalization stage couplable to the output of the accumulation stage for receiving an accumulated output signal therefrom, the normalization stage being arranged to normalize the accumulated output signal to produce a normalized output signal, the normalized output signal corresponding to the phase offset of two successive symbols caused by the frequency offset and the phase offset between a local oscillator and a transmitted input signal;
the phase compensation stage having a further input to which the phase offset is applied to compensate the phase of a subsequently received symbol in the transmitted input signal.

Preferably, the differential detector stage is arranged to receive a transmitted input signal modulated according to a differential modulation scheme such as a

$$\frac{π}{4}$$

Differential Quadrature Phase Shift Keying (DQPSK) modulation scheme.

According to a second aspect of the present invention there is provided a method for estimating frequency offset between a local oscillator and a transmitted input signal in a communication system, the transmitted signal comprising a number of symbols each having an associated phase, the method comprising:
receiving in a differential detector stage a transmitted input signal, the differential detector stage having an input and an output;
compensating in a phase compensation stage for phase errors in an output signal from the differential detector stage, the phase compensation stage having an output;
rotating in a decision-based rotation stage the output signal from the differential detector stage so that the phase of the signal output from the decision-based rotation stage is within a predetermined amount of a predetermined phase angle; the step of rotating being based on a decision made using the output signal from the phase compensation stage, the decision-based rotation stage being couplable to the outputs of the differential detector stage and the phase compensation stage, the decision-based rotation stage having an output signal having a phase;
accumulating in an accumulation stage the output signal from the decision-based rotation stage for a number of symbols in the transmitted input signal, the accumulation stage having an output; and
normalizing in a normalization stage couplable to the output of the accumulation stage the accumulated output signal to produce a normalized output signal; the normalized output signal corresponding to the phase offset of two successive symbols caused by the frequency offset and the phase offset between a local oscillator and a transmitted input signal;
applying the phase offset to a further input of the phase compensation stage to compensate the phase of a subsequently received symbol in the transmitted input signal; and
estimating a frequency offset between a local oscillator and the transmitted input signal from the phase offset.

Preferably, the step of receiving in the differential detector stage a transmitted input signal comprises receiving a transmitted input signal modulated according to a differential modulation scheme such as a

$$\frac{π}{4}$$

Differential Quadrature Phase Shift Keying (DQPSK) modulation scheme.

According to a third aspect of the present invention there is provided a receiver comprising the system defined above.

According to a fourth aspect of the present invention there is provided a method for processing received signals in a communication system comprising the method defined above.

According to a fifth aspect of the present invention there is provided an apparatus for demodulating a signal which has been modulated according to any one or more of a differential phase shift keying (DPSK), an M-ary differential phase shift keying (MDPSK), or a Differential Quadrature Phase Shift Keying (DQPSK) modulation scheme comprising the system defined above.

According to a sixth aspect of the present invention there is provided a demodulation apparatus for the decoding of data, said apparatus comprising the system defined above.

### BRIEF DESCRIPTION OF THE DRAWINGS

Preferred embodiments of the invention will now be described, by way of example, and with reference to the accompanying drawings, in which:

FIG. 1a is a schematic diagram showing the structure of a conventional transmitter system for transmitting signals modulated according to a

$$\frac{π}{4}$$

DQPSK modulation scheme;

FIG. 1b is a schematic diagram showing the structure of a conventional receiver system for receiving signals modulated according to a

$$\frac{π}{4}$$

modulation scheme;

FIG. 2 is a schematic diagram showing a conventional decision-based rotation procedure for use in a

$$\frac{π}{4}$$

DQPSK modulation scheme;

FIG. 3 is a schematic diagram showing the structure of a further conventional receiver system for receiving signals modulated according to a

$$\frac{π}{4}$$

DQPSK modulation scheme;

FIG. 4 is a schematic diagram showing the structure of a receiver system according to a preferred embodiment of the invention for receiving signals modulated according to a

$$\frac{π}{4}$$

DQPSK modulation scheme;

FIG. 5 is a schematic diagram of a combined signal detection and frequency estimation system according to a further preferred embodiment of the present invention;

FIG. 6 is a diagrammatic representation of the control flow of the combined signal detection and frequency estimation system of FIG. 5;

FIG. 7 is a schematic diagram of a combined signal detection and frequency estimation system according to a still further preferred embodiment of the present invention; and FIG. 8 is a diagrammatic representation of the control flow of a combined signal detection and frequency estimation system according to another preferred embodiment of the present invention.

### DESCRIPTION OF PREFERRED EMBODIMENTS

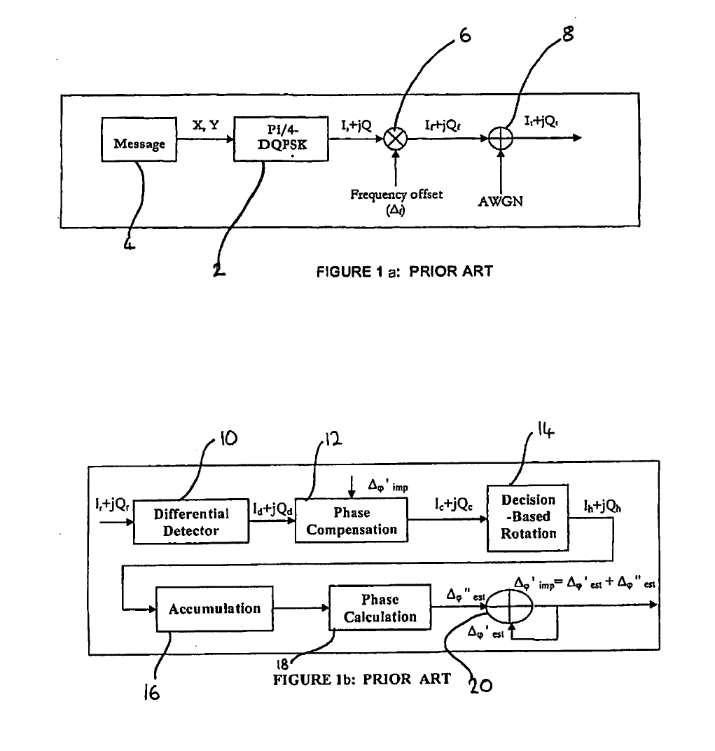

FIG. 1a shows the structure of a conventional transmitter system for transmitting signals modulated according to a

$$\frac{π}{4}$$

DQPSK modulation scheme.

Such a transmitter system may be used to transmit signals which may then be received by the systems according to one or more embodiments of the present invention, as well as the conventional receiver systems aspects of which are shown in FIGS. 1b, 2 and 3.

The transmitter system shown in FIG. 1a comprises an encoder stage 2 for receiving and encoding the message 4 to be transmitted according to a

$$\frac{π}{4}$$

DQPSK modulation scheme. In the following description, it is assumed that the modulated signal has the format (I+jQ) where I and Q are the in-phase and quadrature values respectively. The encoded signal output from the encoder stage 2 may be transmitted over a conventional network such as a wireless network to a receiver for decoding. Due to inaccuracies in the transmitter and receiver oscillators, along with the effect of Doppler Shifting, there are frequency and phase offsets between the received signal and the local carrier in the receiver. There are also many kinds of channel models for transmission networks which will introduce interferences and attenuations. For the purposes of the following description it is assumed that the channel model is Additive White Gaussian Noise (AWGN). In FIG. 1a, there is an induced frequency offset 6 and this is represented as a multiplication of the signal output from the encoder 2 by a frequency offset amount Δ_{f}. Similarly, Additive White Gaussian Noise (AWGN) 8 is generated in the system and this is shown in FIG. 1a as being added to the encoded signal in which a frequency offset 6 has been induced.

The transmitter system of FIG. 1a operates as follows. The message 4 may be represented by a number of symbols k. In

$$\frac{π}{4}$$

DPSK modulation schemes, including

$$\frac{π}{4}$$

DQPSK modulation schemes, the phase of the carrier signal may take one of four values

$$\frac{π}{4}$$

and thus two bits may be represented per symbol. As two bits may be transmitted per symbol, the input binary data may be denoted by X(k) and Y(k).

The input binary data is modulated in the

$$\frac{π}{4}$$

DQPSK encoder stage 2 according to the algorithm:

$$I ( k ) + j Q ( k ) = ( I ( k - 1 ) + j Q ( k - 1 ) ) {ⅇ}^{jΔ ( X ( k ) , Y ( k ) )} \\ when X ( k ) = Y ( k ) = 0 , ΔΦ = \frac{π}{4} \\ when X ( k ) = Y ( k ) = 1 , ΔΦ = \frac{- 3 π}{4} \\ when X ( k ) = 0 , Y ( k ) = 1 , ΔΦ = \frac{3 π}{4} \\ when X ( k ) = 1 , Y ( k ) = 0 , ΔΦ = \frac{- π}{4} \qquad ( 1 )$$

and where:
I(k) is the in-phase component at symbol k;
Q(k) is the quadrature component at symbol k; and
ΔΦ(X(k), Y(k)) is the phase difference based on the binary data X(k) and Y(k).

The frequency offset 6 induced in the encoded signal output from the encoder stage 2 is represented in FIG. 1a as multiplying the signal output from the encoder 2 by a frequency offset amount Δ_{f} giving a new I_{f}(k) and Q_{f}(k), as follows:

$$\begin{matrix}{I}_{f} ( k ) + j {Q}_{f} ( k ) = ( I ( k ) + j Q ( k ) ) {ⅇ}^{j ( 2 πΔ fl + Δφ )} \\ = ( I ( k - 1 ) + j Q ( k - 1 ) ) {ⅇ}^{j ( 2 πΔ fTs + Δ p + Δ Φ ( X ( k ) , Y ( k ) )} \\ = ( I ( k - 1 ) + j Q ( k - 1 ) ) {ⅇ}^{j ( Δ {φ}^{′} + ΔΦ ( X ( k ) , Y ( k ) )}\end{matrix} \qquad ( 2 )$$

where:
Δ_{φ} is the phase offset error at symbol k;
Δₚ is the phase offset difference of successive two symbols (symbol k with symbol k−1);
Tₛ is time interval of one signal symbol;
2πΔ_{f}Tₛ is the phase difference of successive two symbols caused by the frequency offset Δ_{f}; and
Δ_{φ}′=2πΔ_{f}Tₛ+Δₚ is the total phase offset of the successive two symbols caused by frequency offset Δ_{f} and phase offset Δₚ.

It may be seen that, when there is zero frequency offset (Δ_{f}=0) and zero phase offset error (Δₚ=0), there is no additional phase shift between one symbol and the next except the phase difference ΔΦ(X(k),Y(k)) based on the binary data X(k) and Y(k).

Additive White Gaussian Noise (AWGN) 8 is generated in the system to model the AWGN channel and this is shown in FIG. 1a as being added to the encoded signal in which a frequency offset 6 has been induced. After the AWGN channel, the signal is represented by Iₜ and Qₜ and may be denoted as:
Iₜ(k)+jQₜ(k)=I_{f}(k)+jQ_{f}(k)+N_{c}(k)+jNᵢ(k) (3)
where: N_{c}(k) is the in-phase Additive White Gaussian Noise component;
Nᵢ(k) is the quadrature Additive White Gaussian Noise component.

FIG. 1b shows the structure of a conventional receiver system for receiving signals modulated according to a

$$\frac{π}{4}$$

DQPSK modulation scheme and transmitted by, for example, a transmitter system such as that shown in FIG. 1a. Such a receiver system is described in detail in Proakis, Digital Communications, “Chapter 6: Carrier and symbol synchronization,” McGraw-Hill International Editions, Singapore, 3rd edition, 1995.

The receiver system of FIG. 1b comprises a differential detector 10 to receive the incoming transmitted signal. The signal output from the differential detector 10 is applied to the input of a phase compensation stage 12, the output of which is passed to the input of a decision-based rotation stage 14. The signal output from the decision-based rotation stage 14 is applied to an accumulation stage 16 and the accumulated output signal there from is applied to a phase calculation stage 18. The phase calculated in the phase calculation stage 18 is then added in an adder stage 20 to the previous estimated phase offset to obtain a newly estimated value of the phase offset.

The received signal is represented by Iᵣ and Qᵣ and it is assumed that Iᵣ and Qᵣ are digitized and contain the frequency offset to be estimated. Referring to FIG. 1b, the differential detector 10 performs differential detection of one symbol span according to the following algorithm:

$$\begin{matrix}{I}_{d} ( k ) + j {Q}_{d} ( k ) = ( {I}_{r} ( k ) + j {Q}_{r} ( k ) ) ( {I}_{r} ( k - 1 ) - j {Q}_{r} ( k - 1 ) ) \\ = ( {\vert {I}_{r} ( k - 1 ) \vert}^{2} + {\vert {Q}_{r} ( k - 1 ) \vert}^{2} ) {ⅇ}^{j ( {Δφ}^{′} + {Δφ}_{e}^{′} + ΔΦ ( X ( k ) , Y ( k ) ) )}\end{matrix} \qquad ( 4 )$$

where:
I_{d}(k)=Iᵣ(k)Iᵣ(k−1)+Qᵣ(k)Qᵣ(k−1) and
Q_{d}(k)=Qᵣ(k)Iᵣ(k−1)−Iᵣ(k)Qᵣ(k−1)
Δφ_{c}′ is the phase jitter caused by AWGN.

The phase compensation stage 12 uses the previous estimated value of the phase error Δ_{φ}′ᵢₘₚ to compensate the differential detection output according to the algorithm:
I_{c}(k)+jQ_{c}(k)=(|Iᵣ(k−1)|²+|Qᵣ(k−1)|²)e^{j(Δφ′+Δφ}^{_{c}}^{′+ΔΦ(X(k),Y(k)))}e^{-jΔφ′}^{ᵢₘₚ} (5)

As mentioned above in connection with FIG. 1a, the phase offset Δ_{φ}′=2πΔ_{f}Tₛ+Δₚ is the total phase offset of the successive two symbols caused by frequency offset Δ_{f} and phase offset Δₚ, Δφ_{c}′ is the phase jitter caused by AWGN. U.S. Pat. No. 5,574,399 which is directed to a coherent PSK detector which does not require carrier recovery proposes a first method for estimating the frequency offset by initially setting Δ_{f}′=0. An improved method for estimating the frequency offset is described in U.S. Pat. No. 6,038,267 directed to a digital demodulator, a maximum-value selector, and a diversity receiver. In this system, Δ_{f}′ is instead initially set to a fixed value of approximately the right order.

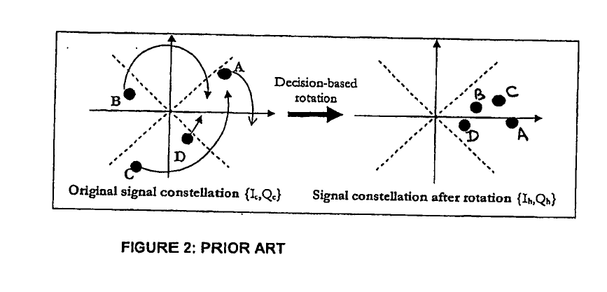

The phase compensated signals I_{c}(k)+jQ_{c}(k) output from the phase compensation stage 12 are passed to the input of the decision-based rotation stage 14 which uses a hard decision to decide the quadrants in which the signals lie. The decision-based rotation stage 14 (which is shown in more detail in FIG. 2 described below) then rotates the phase compensated signals I_{c}(k)+jQ_{c}(k) towards the x-axis of the first quadrant based on that hard decision. Thus, if the signal is originally in the first quadrant (A),

$$a \frac{π}{4}$$

rotation clockwise will be required. If the signal is originally in the second quadrant (B), a

$$\frac{3 π}{4}$$

rotation clockwise will be required. If the signal is originally in the third quadrant (C),

$$a \frac{5 π}{4}$$

rotation clockwise (equivalent to a

$$\frac{3 π}{4}$$

rotation anti-clockwise) will be required. If the signal is originally in the fourth quadrant (D), a

$$\frac{7 π}{4}$$

rotation clockwise (equivalent to a

$$\frac{π}{4}$$

rotation anti-clockwise) will be required. It should be noted that these values are the values on which the

$$\frac{π}{4}$$

DQPSK system of modulation is based. This step is included so that all symbols, irrespective of their quadrant, may be compared with a single value at the next step. This simplifies the comparison.

After the decision-based rotation, the frequency offset may be calculated by measuring the phase of the rotated signal. If a symbol lies on the x-axis, the phase error denoted by Δ_{φ}″ₑₛₜ is zero. This phase is added to the previous estimated phase offset Δ_{φ}′ₑₛₜ to obtain a newly estimated phase offset value Δ_{φ}′ᵢₘₚ. Essentially, the average phase is calculated by summing up all the I and Q signals separately and calculating the phase of the summed I and Q. The accumulation stage 16 performs the summing up of the in-phase I and quadrature Q signals as follows:

$$\begin{matrix}sum I = {\sum }_{0}^{k - 1} {I}_{h} & ( 6 ) \\ sum Q = {\sum }_{0}^{k - 1} {Q}_{h} & ( 7 )\end{matrix}$$

Where k is the number of symbols used for the frequency estimation.

The phase calculation stage 18 computes the arc tangent of

$$[ \frac{sum Q}{sum I} ]$$

to obtain the phase error Δ_{φ}″ₑₛₜ, as shown in FIG. 1b, and updates the estimated value of the phase error Δ_{φ}″ₑₛₜ.

Thus:

$${Δ}_{φ est}^{″} = arctan [ \frac{sum Q}{sum I} ] \qquad ( 8 )$$

The adder stage 20 adds the newly estimated phase error value Δ_{φ}″ₑₛₜ to the previously estimated phase offset value as follows to obtain a newly estimated phase offset value Δ_{φ}′ᵢₘₚ:
Δ_{φ}′ᵢₘₚ=Δ_{φ}′ₑₛₜ+Δ_{φ}″ₑₛₜ (9)
where Δ_{φ}′ᵢₘₚ is the updated total phase offset of the successive two symbols caused by frequency offset Δ_{f} and phase offset Δₚ.

The phase compensation stage 12 in FIG. 1b is thus arranged to implement a complex multiplication equation. In order to obtain the sine and cosine of the phase offset value Δ_{φ}′ᵢₘₚ, a complex trigonometric function calculation must implemented in the phase compensation stage 12.

As mentioned above, the decision-based rotation stage 14 is shown in more detail in FIG. 2. In particular, the rotation of the phase compensated signals I_{c}(k)+jQ_{c}(k) towards the x-axis of the first quadrant based on that hard decision is shown. Thus, FIG. 2 shows a

$$\frac{π}{4}$$

rotation clockwise of the signal (A) if it is in the first quadrant,

$$a \frac{3 π}{4}$$

rotation clockwise of the signal (B) if it is originally in the second quadrant, a

$$\frac{5 π}{4}$$

rotation clockwise (equivalent to a

$$\frac{3 π}{4}$$

rotation anti-clockwise) of the signal (C) if it is originally in the third quadrant, and a

$$\frac{7 π}{4}$$

rotation clockwise (equivalent to a

$$\frac{π}{4}$$

rotation anti-clockwise) of the signal (D) if it is originally in the fourth quadrant.

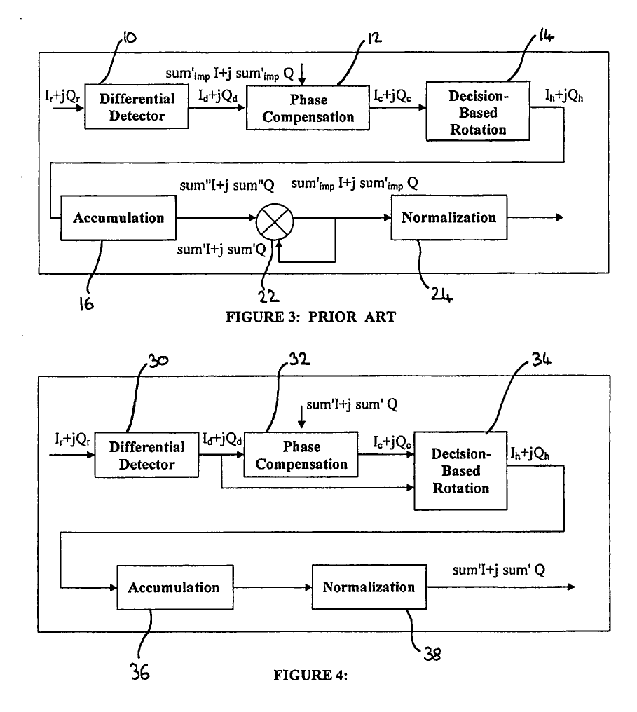

An alternative conventional frequency offset estimation method avoids the arc tangent calculation (equation 8 above) in the phase calculation stage 18 and the trigonometric function calculation (equation 5 above) in the phase compensation stage 12. A receiver for use in this alternate frequency offset estimation method is shown in FIG. 3. The same reference numerals as those used in FIG. 1b have been used in connection with FIG. 3 to denote identical components in the two receiver systems. The receiver system of FIG. 3 comprises a differential detector 10 to receive the incoming transmitted signal. The output signal from the differential detector 10 is applied to the input of a phase compensation stage 12, the output of which is passed to the input of a decision-based rotation stage 14. The output signal from the decision-based rotation stage 14 is applied to an accumulation stage 16 and the accumulated output signal therefrom which comprises the newly estimated phase offset value of the signal is applied to a multiplier stage 22. The multiplier stage 22 multiplies the accumulated output signal by the previously estimated phase offset value. The output signal from the multiplier stage 22 is applied to the input of a normalization stage 24 to obtain a newly estimated phase offset value and therefore a newly estimated value of the frequency offset.

Thus, the receiver system of FIG. 3 differs from that shown in FIG. 1b in that instead of applying the phase offset value Δ_{φ}′ᵢₘₚ to the phase compensation stage 12 to compensate the phase of the incoming signal (equation 5 above), the system and method shown in FIG. 3 applies the sum′ᵢₘₚI+jsum′ᵢₘₚQ into the phase compensation stage 12 directly. Furthermore, the adder stage 20 of the system of FIG. 1b is replaced by the multiplier stage 22 (as shown in FIG. 3) to implement the accumulation of the newly estimated phase to the previously estimated phase using the algorithm:
sum′ᵢₘₚI+jsum′ᵢₘₚQ=(sum′I+jsum′Q)(sum″I+jsum″Q) (10)

Due to the accumulation of the signals Iₕ(k)+jQₕ(k) and the multiplication of the newly estimated value (sum″I+jsum″Q) by the previously estimated value (sum′+jsum′Q) (equation 10), the amplitude of the sum′ᵢₘₚI+jsum′ᵢₘₚQ may increase greatly after a number of frequency estimation cycles. To make the amplitude of sum′ᵢₘₚI+jsum′ᵢₘₚQ relatively stable, the normalization stage 24 is used to adjust the amplitude of sum′ᵢₘₚI+jsum′ᵢₘₚQ.

As mentioned above, there are a number of problems in the frequency offset estimation algorithms described with respect to the systems illustrated in FIGS. 1b and 3. Firstly, these algorithms are complex. In particular, in the method described above and illustrated by the system of FIG. 1b, two trigonometric function calculations are required, namely the calculation of an arc tangent and the calculation of the sine/cosine.

Furthermore, in the systems of FIGS. 1b and 3, complex hardware is included. For example, in the system of FIG. 1b there are two complex multipliers, namely the differential detector and the phase compensation stage and in the system of FIG. 3, there are three complex multipliers, namely the differential detector, the phase compensation stage and the multiplier stage after the accumulation stage, as well as a normalization stage.

Another disadvantage of the conventional algorithms described above is that they rely heavily on the preceding estimation and are therefore not suitable for handling the transition from the state where no data is being transmitted to the state where data is being transmitted. Furthermore, when no data is being transmitted, noise will still be present in the channel and this may affect the frequency offset estimation system resulting in a poor and unstable frequency offset estimation.

Also, should the initial estimation error incorrectly move the signal into the neighboring quadrant in the X-Y coordinate, the conventional systems cannot generally correct the estimation error by themselves and this will result in the failure of the communication. Furthermore, the above-described conventional algorithms are unable to handle the transition from a no data transmission state to a data transmission state.

A simplified frequency estimation apparatus and method and a combined signal detection and frequency estimation system and method are proposed by embodiments of the present invention, preferred embodiments of which are illustrated in FIGS. 4 to 8. One or more preferred embodiments reduce the complexity of the frequency offset estimation apparatus without introducing any performance penalty, and the combined signal detection and frequency offset estimation system and method according to an embodiment of the invention may handle the transition from a no data transmission state to a data transmission state.

A first preferred embodiment of the invention is shown in FIG. 4 and is described with reference to an apparatus and method for estimating frequency offset in a signal which has been modulated according to, for example, a

$$\frac{π}{4}$$

Differential Phase Shift Keying (DPSK) or Differential Quadrature Phase Shift Keying (DQPSK) modulation scheme and transmitted by a transmitter such as that shown in FIG. 1a. An incoming modulated signal is received on a carrier and is applied to the input of a differential detector 30. The output signal of the differential detector 30 is applied to the inputs of a phase compensation stage 32 and a decision-based rotation stage 34. The output signal from the phase compensation stage 32 is also applied to an input of the decision-based rotation stage 34. The output signal from the decision-based rotation stage 34 is applied to the input of an accumulation stage 36, the output signal from which is applied to the input of a normalization stage 38. The output signal from the normalization stage 38 is the newly estimated total phase offset of the successive two symbols caused by frequency offset Δ_{f} and phase offset Δₚ. The output signal from the normalization stage 38 is also applied to a further input of the phase compensation stage 32 to compensate the detected signals from the differential detector 30.

The system of FIG. 4 operates as follows. The received signal is represented by Iᵣ and Qᵣ and it is assumed that Iᵣ and Qᵣ are digitized and contain the frequency offset to be estimated. The differential detector 30 performs differential detection of one symbol span according to the following algorithm:

$$\begin{matrix}{I}_{d} ( k ) + {jQ}_{d} ( k ) = ( {I}_{r} ( k ) + {jQ}_{r} ( k ) ) ( {I}_{r} ( k - 1 ) - {jQ}_{r} ( k - 1 ) ) \\ = ( {\vert {I}_{r} ( k - 1 ) \vert}^{2} + {\vert {Q}_{r} ( k - 1 ) \vert}^{2} ) {ⅇ}^{j ( {Δφ}^{′} + {Δφ}_{c}^{′} + ΔΦ ( X ( k ) , Y ( k ) ) )}\end{matrix}$$

where:
I_{d}(k)=Iᵣ(k)Iᵣ(k−1)+Qᵣ(k)Qᵣ(k−1) and
Q_{d}(k)=Qᵣ(k)Iᵣ(k−1)−Iᵣ(k)Qᵣ(k−1)
Δφ_{c}′ is the phase jitter caused by AWGN.

The output signal from the differential detector 30 is applied to the input of the phase compensation stage 32 where the signal is compensated for the phase error (offset). The phase compensation stage 32 uses the previous estimated value of the phase error (offset) Δ_{φ}′ᵢₘₚ to compensate the differential detection output according to the algorithm:
I_{c}(k)+jQ_{c}(k)=(|Iᵣ(k−1)|²+|Qᵣ(k−1)|²)e^{j(Δφ′+Δφ}^{_{c}}^{′+ΔΦ(X(k),Y(k)))}e^{-jΔφ′}^{ᵢₘₚ}

As mentioned above in connection with FIG. 1a, the phase offset Δ_{φ}′=2πΔ_{f}Tₛ+Δₚ is the total phase offset of the successive two symbols caused by frequency offset Δ_{f} and phase offset Δₚ.

The phase compensated signals I_{c}(k)+jQ_{c}(k) output from the phase compensation stage 32 are applied to the input of the decision-based rotation stage 34 which uses a hard decision to decide the quadrants in which the signals lie. The decision-based rotation stage 34 then rotates the original differential detector output signals I_{d}(k)+jQ_{d}(k) (without phase compensation) towards the x-axis of the first quadrant based on the aforementioned decision. The output signal from the decision-based rotation stage 34 is then added in the accumulation stage 36 to outputs of the decision-based rotation stage 34 and the accumulated output is then normalized in the normalization stage 38 in the same manner as that described above with respect to FIG. 3.

To obtain the estimated phase offset value, the estimated phase offset value (sum′I+jsum′Q) is further applied to a further input of the phase compensation stage 32 to correct the phase of the detected signals. Therefore, the resulting estimated output is related to the total phase offset of the successive two symbols caused by frequency offset Δ_{f} and phase offset Δₚ, not the residual phase offset. Thus, there is no need to accumulate the successive estimated phase values, thereby enabling the multiplier of the system of FIG. 3 to be omitted. This architecture will simplify the hardware implementation without performance penalty as the hard decision used in frequency estimation is based on the signals with phase compensation.

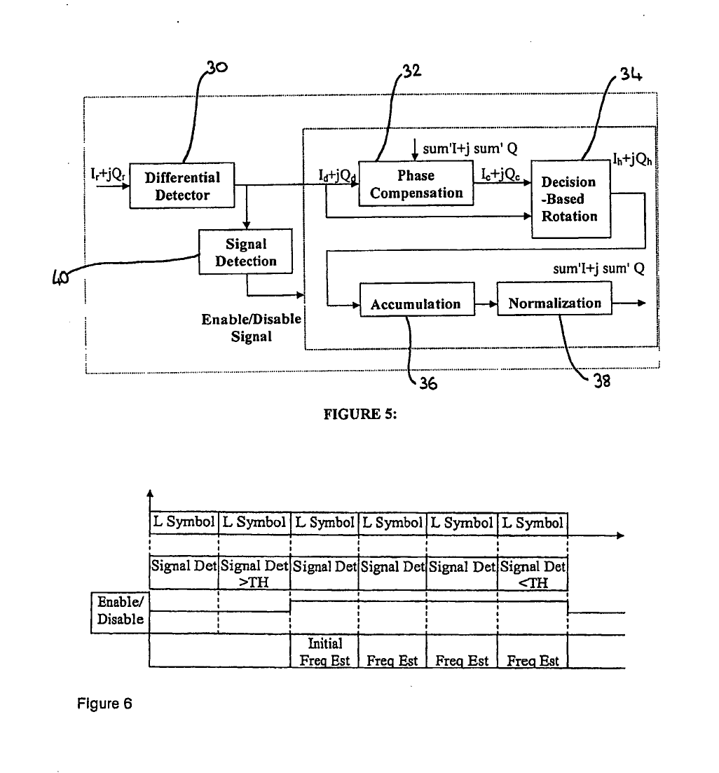

A preferred combined signal detection and frequency estimation system according to a preferred embodiment of the present invention is shown in FIG. 5. In this embodiment, the signal detection is utilized to monitor the channel status. The same reference numerals as those used in FIG. 4 have been used in connection with FIG. 5 to denote identical components in the two systems.

The system of FIG. 5 differs from that shown in FIG. 4 in that a signal detection stage 40 is included in the system of FIG. 5, the input of which is taken from the output of the differential detector 30. The output of the signal detection stage 40 is used to enable or disable the phase estimation system comprising the phase compensation stage 32, the decision-based rotation stage 34, the accumulation stage 36 and the normalization stage 38.

The amplitudes of the outputs of the differential detector 30 may be used to estimate the signal power. If the sum of the amplitudes over L symbols is greater than a pre-set (predetermined) threshold, the channel may be assumed to be receiving transmitted data, otherwise the channel is assumed to be idle (that is, it is assumed that no transmitted data is being received). The sum of the amplitudes of the outputs of the differential detector 30 over L symbols is given by:

$$\begin{matrix}{\sum }_{l = 1}^{L} \vert {I}_{dl} ( k ) + {jQ}_{dl} ( k ) \vert = {\sum }_{l = 1}^{L} ( \begin{matrix}{\vert {I}_{rl} ( k - 1 ) \vert}^{2} + \\ {\vert {Q}_{rl} ( k - 1 ) \vert}^{2}\end{matrix} ) \times \\ = \vert {ⅇ}^{j ( Δφ {l}^{′} + ΔΦ l ( X ( k ) , Y ( k ) ) )} \vert \\ = {\sum }_{l = 1}^{L} ( {\vert {I}_{rl} ( k - 1 ) \vert}^{2} + {\vert {Q}_{rl} ( k - 1 ) \vert}^{2} )\end{matrix} \qquad ( 11 )$$

In the first instance, the absolute values of the differential detector output over L symbols are summated. If the averaged result is greater than the predetermined threshold, an enable signal will be generated and the phase offset estimation and therefore the frequency offset estimation will be performed. If the averaged result is less than the predetermined threshold, a disable signal will be generated and the phase and frequency offset estimation will be ceased.

FIG. 6 illustrates the control of the combined signal detection and frequency offset estimation system of FIG. 5. Each column represents a period during which L symbols may be received. As shown, in the first (far left-hand) column, a signal is detected and in the second column, a signal is again detected. If the sum of the signals received in the first two columns is greater than the predetermined threshold value, the frequency offset estimation is performed and this is continued for the periods of those third and subsequent columns in which a signal above the predetermined threshold value is again detected. In the final (far right-hand) column, the signal level has fallen below the predetermined threshold value and, therefore, at the end of the period covered by this column, frequency offset estimation ceases.

An enable signal is generated when the signal level exceeds the predetermined threshold value and a disable signal is generated when the signal level falls below the predetermined threshold value. These two signals may be combined in a single enable/disable signal.

In a further preferred embodiment, instead of the amplitude values of the detected signals output from the differential detector, the squared values of the amplitudes of the I and Q components of the differential detector output signals may be used to estimate the signal strength (and thereby control the generation of the enable/disable signal) according to the following equation:

$${\sum }_{l = 1}^{L} {\vert {I}_{dl} ( k ) + {jQ}_{dl} ( k ) \vert}^{2} = {\sum }_{l = 1}^{L} {( {\vert {I}_{rl} ( k - 1 ) \vert}^{2} + {\vert {Q}_{rl} ( k - 1 ) \vert}^{2} )}^{2} \qquad ( 12 )$$

In a still further preferred embodiment, the sum of the absolute values of the I and Q components of the detected signals output from the differential detector may be used to estimate the signal strength (and thereby control the generation of the enable/disable signal) according to the following equation:

$${\sum }_{l = 1}^{L} ( \vert {I}_{dl} ( k ) \vert + \vert {Q}_{dl} ( k ) \vert ) = {\sum }_{l = 1}^{L} ( {\vert {I}_{rl} ( k - 1 ) \vert}^{2} + {\vert {Q}_{rl} ( k - 1 ) \vert}^{2} ) ( \vert cos ( {Δ}_{φ l}^{′} + {Δ}_{φ l} ( X ( k ) , Y ( k ) ) ) \vert + \vert sin ( {Δ}_{φ l}^{′} + {Δ}_{φ l} ( X ( k ) , Y ( k ) ) \vert ) \qquad ( 13 )$$

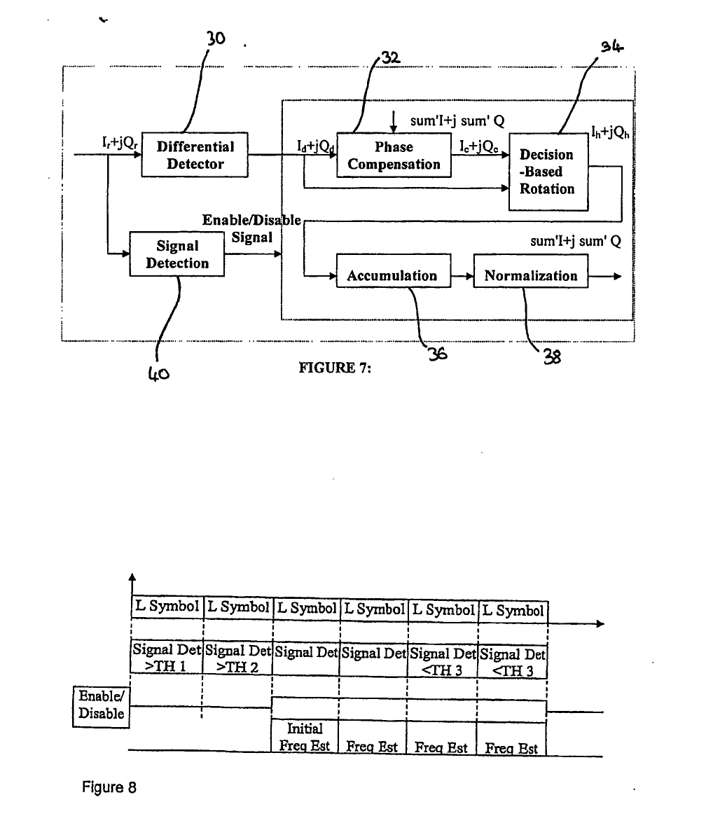

In another preferred embodiment, instead of using the detected signals output from the differential detector 30 to control the generation of the enable/disable signal, as in the system of FIG. 5, the signals at the input of the differential decoder 30 may be used. Such an embodiment is shown in FIG. 7. This is the sole difference between the embodiments of FIGS. 5 and 7 and the same reference numerals have been used in both figures to denote identical components in the two systems.

In order to improve the reliability of signal detection, the control flow of the combined signal detection and frequency offset estimation system may be modified slightly, as shown in FIG. 8 which illustrates a system according to a further preferred embodiment of the present invention.

When the channel is idle, that is, the system is not receiving any transmitted data, two thresholds may be used to detect the start of reception of transmitted data. In FIG. 8, each column represents a period during which L symbols may be received. During the first period (denoted by the first (far left-hand) column), if the summated amplitudes of the signals to be used to determine the signal strength are greater than a first predetermined threshold value 1, a second determined signal strength result will be used to compare with a second predetermined threshold value 2 in the second column of FIG. 8. The channel will be asserted to be busy, that is, data is being received, only if the second determination of signal strength is larger than the second threshold value 2.

When the channel is busy (as in the third and fourth columns from the left-hand side of FIG. 8 and frequency offset is therefore carried out), the signal detector will continuously compare the determined signal strength results with a third predetermined threshold value 3. The channel will be asserted to be idle (and no frequency offset estimation will occur) only if the determined signal strength results are less than the third threshold value 3 over two consecutive estimation periods (as shown in the fifth and sixth columns of FIG. 8).

The selection of the above three thresholds may be based on the real system threshold 1 and threshold 2 may be set to the same value or two different values, preferably threshold 1 is less than threshold 2. Threshold 3 may be set to the same value as threshold 2 or to a different value.

The systems and methods according to one or more preferred embodiment of the invention may be applied to the forward frequency estimation schemes based on hard decision-based rotation.

With the method and apparatus embodying the invention, a simpler demodulation apparatus for modulation schemes such as

$$\frac{π}{4}$$

Differential Quadrature Phase Shift Keying (DQPSK) modulation schemes may therefore be derived. The embodiments of the invention thereby assist in reducing the demodulation complexity of such schemes.

Depending on the application in which the apparatus and methods embodying the invention are to be used, all or part of the apparatus/process steps described above may be constructed or integrated in hardware, for example, an ASIC. Alternatively, part or all of the apparatus/process steps described above may be implemented in software.

In conclusion, the systems and methods according to the present invention may be particularly useful in the production of devices for use as a receiver for a communication system.

The phase offset estimation system and method according to one or more preferred embodiments of the present invention simplify the algorithms used, for example to just one complex multiplication stage, without performance penalty. Furthermore, the combined signal detection and phase estimation system and method according to a preferred embodiment may handle the transition from idle channel to busy channel thereby improving the performance of the phase offset estimation algorithm.

Various modifications to the embodiments of the present invention described above may be made. For example, other components and method steps can be added or substituted for those above. Also, whilst preferred embodiments of the invention have been described above in connection with an apparatus and method for estimating the phase offset in a signal modulated according to a

$$\frac{π}{4}$$

Differential Quadrature Phase Shift Keying (DQPSK) modulation scheme, this is merely an example of a type of modulated signal to which embodiments of the present invention may be applied. One or more preferred embodiments may be applied to signals which have been modulated according to alternative modification schemes. Thus, although the invention has been described above using particular embodiments, many variations are possible within the scope of the claims, as will be clear to the skilled reader, without departing from the spirit and scope of the invention.

1. A system for estimating phase offset between a local oscillator and a transmitted input signal in a communication system, the transmitted signal comprising a number of symbols each having an associated phase, the system comprising:
a differential detector stage for receiving a transmitted input signal, the differential detector stage having an input and an output;
a phase compensation stage for compensating for phase errors in an output signal from the differential detector stage, the phase compensation stage having an output;
a decision-based rotation stage couplable to the outputs of the differential detector stage and the phase compensation stage, the decision-based rotation stage having an output signal having a phase, the decision-based rotation stage being arranged to rotate the output signal from the differential detector stage so that the phase of the signal output from the decision-based rotation stage is within a predetermined amount of a predetermined phase angle, the decision-based rotation stage being arranged to rotate the output signal from the differential detector stage based on a decision made using the output signal from the phase compensation stage;
an accumulation stage couplable to receive and accumulate the output signal from the decision-based rotation stage for a number of symbols in the transmitted input signal, the accumulation stage having an output; and
a normalization stage couplable to the output of the accumulation stage for receiving an accumulated output signal therefrom, the normalization stage being arranged to normalize the accumulated output signal to produce a normalized output signal; the normalized output signal corresponding to the phase offset of two successive symbols caused by the frequency offset and the phase offset between a local oscillator and a transmitted input signal;
the phase compensation stage having a further input to which the phase offset is applied to compensate the phase of a subsequently received symbol in the transmitted input signal.

2. A system according to claim 1, wherein the differential detector stage is arranged to receive a transmitted input signal modulated according to a Differential Quadrature Phase Shift Keying (DQPSK) modulation scheme.

3. A system according to claim 1, wherein the predetermined phase angle is zero.

4. A system according to claim 2 wherein the modulation scheme is a
$$\frac{π}{4}$$
(DQPSK) modulation scheme.

5. A system according to claim 1, further comprising a signal detection stage for detecting if a number of symbols in the transmitted input signal have a summed amplitude greater than a predetermined threshold value over a predetermined time period.

6. A system according to claim 5, wherein the signal detection stage is arranged to generate a signal for controlling operation of the system.

7. A system according to claim 6, wherein the signal detection stage is arranged to generate a signal to enable the operation of the system if the number of symbols in the transmitted input signal have a summed amplitude which is determined to be greater than a predetermined threshold value over a predetermined time period.

8. A system according to claim 6, wherein the signal detection stage is arranged to generate a signal to disable the operation of the system if the number of symbols in the transmitted input signal have a summed amplitude determined to be less than a predetermined threshold value over a predetermined time period.

9. A system according to claim 5, wherein the signal detection stage is couplable to the output of the differential detector stage.

10. A system according to claim 5, wherein the signal detection stage is couplable to the input of the differential detector stage.

11. A system according to claim 6, wherein the signal detection stage is arranged to generate a signal to enable the operation of the system if the number of symbols in the transmitted input signal have a summed amplitude which is determined to be greater than a first predetermined threshold value over a first predetermined time period and if the number of symbols in the transmitted input signal have a summed amplitude determined to be greater than a second predetermined threshold value over a second predetermined time period.

12. A system according to claim 11, wherein the first predetermined threshold value is the same as the second predetermined threshold value.

13. A system according to claim 11, wherein the second predetermined threshold value is greater than the first predetermined threshold value.

14. A system according to claim 11, wherein the signal detection stage is arranged to generate a signal to disable the operation of the system if the number of symbols in the transmitted input signal have a summed amplitude which is determined to be less than a third predetermined threshold value over a further predetermined time period.

15. A system according to claim 14, wherein the third predetermined threshold value is the same as the second predetermined threshold value.

16. A method for estimating phase offset between a local oscillator and a transmitted input signal in a communication system, the transmitted signal
comprising a number of symbols each having an associated phase, the method comprising:
receiving in a differential detector stage a transmitted input signal, the differential detector stage having an input and an output;
compensating in a phase compensation stage for phase errors in an output signal from the differential detector stage, the phase compensation stage having an output;
rotating in a decision-based rotation stage the output signal from the differential detector stage so that the phase of the signal output from the decision-based rotation stage is within a predetermined amount of a predetermined phase angle; the step of rotating being based on a decision made using the output signal from the phase compensation stage, the decision-based rotation stage being couplable to the outputs of the differential detector stage and the phase compensation stage, the decision-based rotation stage having an output signal having a phase;
accumulating in an accumulation stage the output signal from the decision-based rotation stage for a number of symbols in the transmitted input signal, the accumulation stage having an output; and
normalizing in a normalization stage couplable to the output of the accumulation stage to normalize the accumulated output signal to produce a normalized output signal; the normalized output signal corresponding to the phase offset of two successive symbols caused by the frequency offset and the phase offset between a local oscillator and a transmitted input signal;
applying the phase offset to a further input of the phase compensation stage to compensate the phase of a subsequently received symbol in the transmitted input signal; and
estimating a phase offset between a local oscillator and the transmitted input signal from the phase offset.

17-30. (canceled)

31. A receiver comprising the system of claim 1.

32-38. (canceled)
